(19) United States
(12) Patent Application Publication
(10) Pub. No.: US 2021/0210536 A1
(43) Pub. Date: Jul. 8, 2021

(54) SEMICONDUCTOR DEVICE PACKAGE AND METHOD FOR MANUFACTURING THE SAME

(71) Applicant: Advanced Semiconductor Engineering, Inc., Kaohsiung (TW)

(72) Inventors: Wei-Wei LIU, Kaohsiung (TW); Huei-Siang WONG, Kaohsiung (TW)

(73) Assignee: Advanced Semiconductor Engineering, Inc., Kaohsiung (TW)

(21) Appl. No.: 16/734,044

(22) Filed: Jan. 3, 2020

(51) Int. Cl. H01L 27/146

(52) U.S. Cl. CPC H01L 27/14623; H01L 27/14627; H01L 27/14687; H01L 27/14685; H01L 27/14636

(57) ABSTRACT

A semiconductor package includes a semiconductor device and a second substrate. The semiconductor device is disposed on, and electrically connected to, the second substrate. The semiconductor device includes a first substrate and a multi-layered structure. The multi-layered structure is disposed on a top surface of the first substrate and a layer of the multi-layered structure extends outwardly beyond a lateral edge of a topmost surface of the multi-layered structure.

### BACKGROUND

### 1. Technical Field

The present disclosure relates to a semiconductor device, a semiconductor package and a method for manufacturing the same.

### 2. Description of the Related Art

Optoelectronic devices, such as a light sensing device, image sensing device, or fingerprint recognition devices, are used in consumer electronic products. An optoelectronic device may contain a plurality of stacked optical layers disposed on a sensing region of a semiconductor die. In the manufacture of an optoelectronic devices, a pad of the semiconductor die may be covered by the stacked optical layers, and therefore, additional operations, such as a slicing and/or physical bombardment, should be carried out to remove a portion of the stacked optical layers to expose the pad, which increases the production cost and time. In addition, delamination may occur due to the stress caused by slicing and/or physical bombardment.

### SUMMARY

In some embodiments, the present disclosure provides a semiconductor device. The semiconductor device includes a first substrate and a multi-layered structure. The multi-layered structure is disposed on a top surface of the first substrate and a layer of the multi-layered structure extends outwardly beyond a lateral edge of a topmost surface of the multi-layered structure.

In some embodiments, the present disclosure provides a semiconductor device. The semiconductor device includes a first substrate and a collimating structure. The first substrate has a sensing region and a pad. The collimating structure is disposed on the sensing region of the first substrate and exposes the pad of the first substrate. A length of a top surface of the collimating structure is smaller than a length of a bottom surface of the collimating structure.

In some embodiments, the present disclosure provides a semiconductor package including a semiconductor device and a second substrate. The semiconductor device includes a first substrate and a multi-layered structure. The multi-layered structure is disposed on a top surface of the first substrate and a layer of the multi-layered structure extends outwardly beyond a lateral edge of a topmost surface of the multi-layered structure. The semiconductor device is disposed on, and electrically connected to, the second substrate.

In some embodiments, a semiconductor package includes a semiconductor device and a second substrate. The semiconductor device includes a first substrate and a collimating structure. The first substrate has a sensing region and a pad. The collimating structure is disposed on the sensing region of the first substrate and exposes the pad of the first substrate. A length of a top surface of the collimating structure is smaller than a length of a bottom surface of the collimating structure. The semiconductor device is disposed on, and electrically connected to, the second substrate.

In some embodiments, a method of manufacturing a semiconductor package includes the following operations. A semiconductor device is provided. The semiconductor device includes a first substrate and a multi-layered structure. The multi-layered structure is disposed on a top surface of the first substrate and a layer of the multi-layered structure extends outwardly beyond a lateral edge of a topmost surface of the multi-layered structure. The semiconductor device is disposed on a top surface of a second substrate and electrically connected to the second substrate by wire bonding.

### BRIEF DESCRIPTION OF THE DRAWINGS

Aspects of some embodiments of the present disclosure are readily understood from the following detailed description when read with the accompanying figures. Various structures may not be drawn to scale, and the dimensions of the various structures may be arbitrarily increased or reduced for clarity of discussion.

FIG. 1 is a schematic cross-sectional view of a semiconductor device in accordance with comparative embodiments.

FIG. 2A is a schematic cross-sectional view of a semiconductor device in accordance with some embodiments of the present disclosure.

FIG. 2B is a schematic cross-sectional view of a semiconductor device in accordance with some embodiments of the present disclosure.

FIG. 2C is a schematic top view of a semiconductor device in accordance with some embodiments of the present disclosure.

FIG. 3 is a schematic cross-sectional view of a semiconductor device in accordance with some embodiments of the present disclosure.

FIG. 4 is a schematic cross-sectional view of a semiconductor device in accordance with some embodiments of the present disclosure.

FIG. 5 is a schematic cross-sectional view of a semiconductor device in accordance with some embodiments of the present disclosure.

FIG. 6 is a schematic cross-sectional view of a semiconductor device package in accordance with some embodiments of the present disclosure.

FIG. 7 is a schematic cross-sectional view of a semiconductor device package in accordance with some embodiments of the present disclosure.

FIG. 8A, FIG. 8B, FIG. 8C, FIG. 8D, FIG. 8E, FIG. 8F, FIG. 8G, FIG. 8H, FIG. 8I, FIG. 8J and FIG. 8K illustrate operations of manufacturing a semiconductor device in accordance with some embodiments of the present disclosure.

Common reference numerals are used throughout the drawings and the detailed description to indicate the same or similar components. Embodiments of the present disclosure will be readily understood from the following detailed description taken in conjunction with the accompanying drawings.

### DETAILED DESCRIPTION

The following disclosure provides for many different embodiments, or examples, for implementing different features of the provided subject matter. Specific examples of components and arrangements are described below to explain certain aspects of the present disclosure. These are, of course, merely examples and are not intended to be limiting. For example, the formation or disposal of a first feature over or on a second feature in the description that follows may include embodiments in which the first and second features are formed or disposed in direct contact, and may also include embodiments in which additional features are formed or disposed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein the term “opaque” may refer to a structure or a layer which does not allow a light within a specific wavelength range, such as a visible light or an invisible light, to pass through, and the term “transparent” may refer to a structure or a layer which allows a light within a specific wavelength range, such as a visible light or an invisible light, to pass through.

As used herein the term “optically-sensitive material” may refer to a material sensitive to a light within a specific wavelength range in an optical curing operation, and the term “optically-cured material” may refer to the optically-sensitive material after being optically cured by the light. Some properties or characteristic of the optically-sensitive material may be changed after curing, and are different from those before curing.

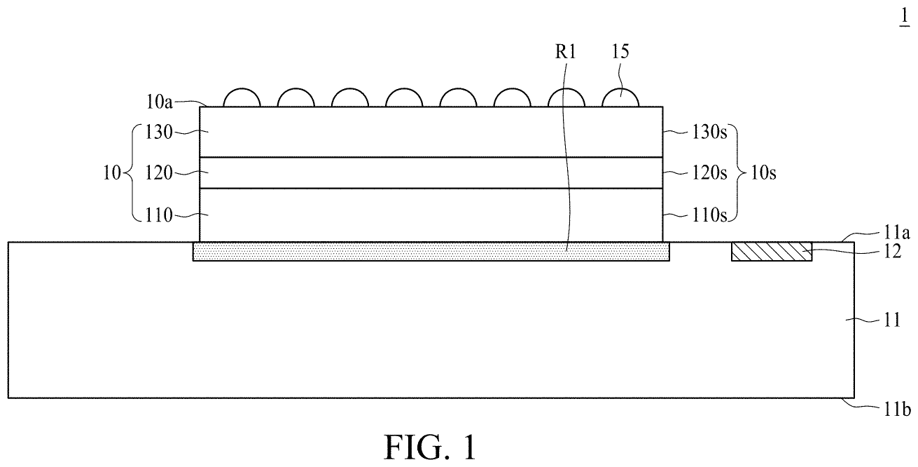

FIG. 1 is a schematic cross-sectional view of a semiconductor device 1 in accordance with comparative embodiments. The semiconductor device 1 includes a substrate 11 (e.g., a wafer), a multi-layered structure 10, and a light concentrating layer (e.g. an array of microlens) 15. The substrate 11 has a top surface 11a and a bottom surface 11b. The top surface 11a of the substrate 11 includes an optical sensing region R1 and a pad 12. In a method for manufacturing the semiconductor device 1, a first layer 110 of the multi-layered structure 10 is formed onto the top surface of the substrate 11, e.g., by spin coating and then layers 120 and 130 are formed thereon in a similar manner. The multi-layered structure 10 covers the entire surface of the substrate 11. To expose the pad 12 for electrically connecting to an external circuit or device, additional operations, such as slicing or physical bombardment, are carried out to remove a portion of the multi-layered structure 12 and the light concentrating layer 15 disposed thereon. After such operation, the multi-layered structure 10 may have a planar sidewall 10s (e.g., the sidewall 130s of the layer 130, the side wall 120s of the layer 120, and the side wall 110s of the layer 110 are substantially coplanar) which is substantially perpendicular to the top surface 10a. In addition, the roughness of the sidewall 10s is increased due to the slicing and/or physical bombardment operation.

The present disclosure describes techniques suitable for the manufacture of a semiconductor device including a substrate and a multi-layered structure disposed thereon. The resulting multi-layered structure has a different configuration as compared to the comparative embodiments and the pad of the substrate can be exposed without carrying out slicing and/or physical bombardment. The semiconductor device or semiconductor package according to the present disclosure has the advantages of lower cost, faster production and less delamination as compared to the comparative embodiments.

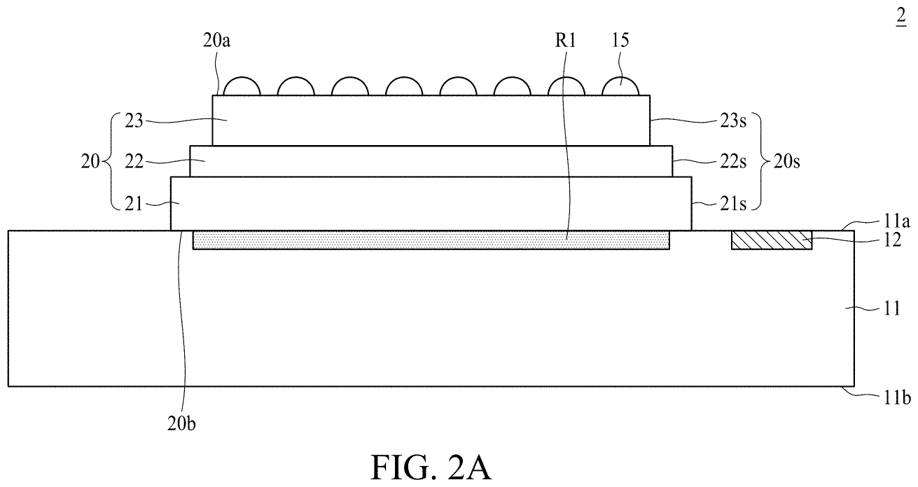

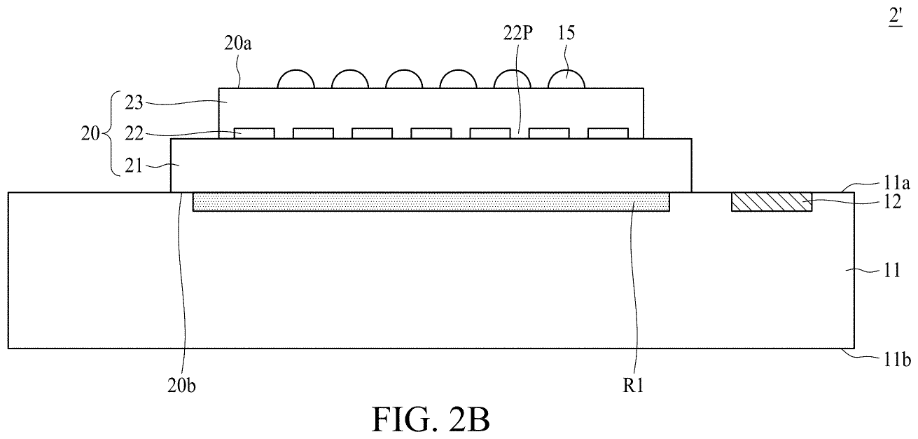

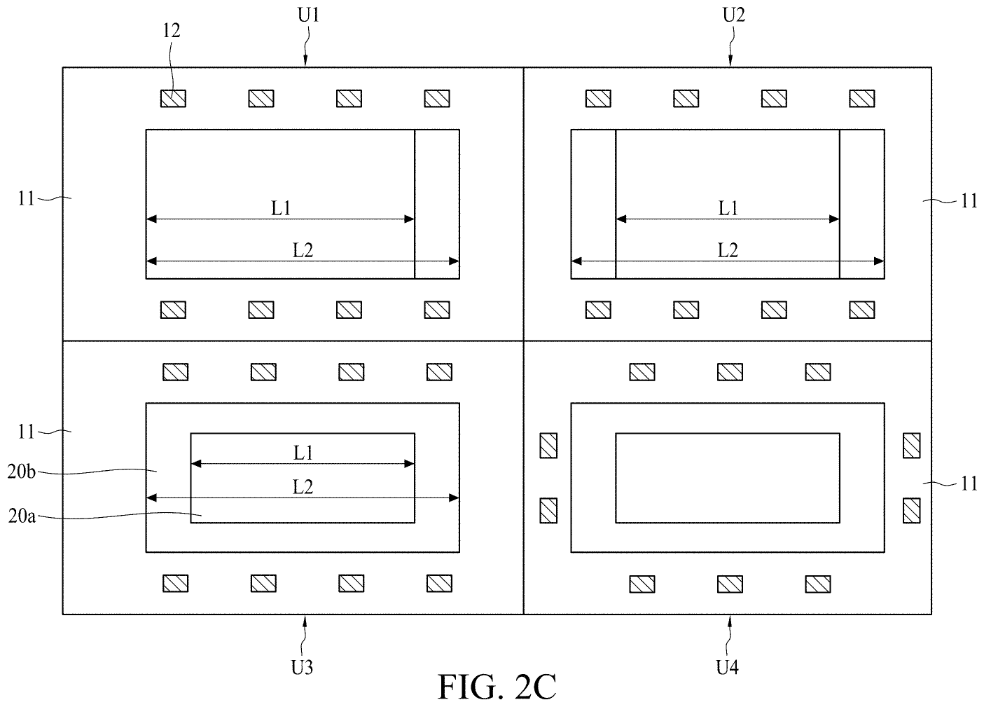

FIG. 2A is a schematic cross-sectional view of a semiconductor device 2 in accordance with some embodiments of the present disclosure. The semiconductor device 2 includes a substrate 11 and a multi-layered structure 20.

The substrate 11 of the semiconductor device may be, for example, a semiconductor substrate, such as a silicon substrate or another suitable semiconductor substrate. In some embodiments, the substrate 11 may be a semiconductor chip, such as a silicon chip. In some embodiments, the substrate 11 may be a semiconductor wafer, such as a silicon wafer, and includes a plurality of semiconductor chips.

The substrate 11 has a top surface 11a and a bottom surface 11b. The top surface 11a of substrate 11 includes a sensing region R1 and a pad 12. The pad 12 is located outside the sensing region R1. In some embodiments, the sensing region R1 is an optical sensing region and the pad 12 is located in a non-optical sensing region.

The multi-layered structure 20 is disposed on the top surface 11a of the substrate 11. The multi-layered structure 20 may cover the sensing region R1 but does not cover the pad 12 of the substrate 11. The multi-layered structure 20 includes a plurality of layers, e.g., 21, 22 and 23. The multi-layered structure 20 may include two or more layers, three or more layers, four or more layers, five or more layers, or more layers. In some embodiments, the multi-layered structure 20 may have a thickness of 100 μm or less, 90 μm or less, 80 μm or less, 70 μm or less, 60 μm or less, 50 μm or less, 40 μm or less, 30 μm or less, 20 μm or less, or less.

The layers (e.g., 21, 22, 23) of the multi-layered structure 20 may be optical layers, such as an optically transparent layer, a light blocking layer, or other optical layers. In some embodiments, the multi-layered structure 20 includes one or more optically transparent layers and one or more light blocking layers stacked alternately. The light blocking layer(s) may define a plurality of apertures. The apertures in different layers may aligned with each other and further aligned with a respective one of microlens to collimate the light. In some embodiments, the multi-layered structure may function as a collimating structure. In some embodiments, the multi-layered structure may contain a filter layer and light reflecting layer.

FIG. 2B is a schematic cross-sectional view of a semiconductor device 2′ in accordance with some embodiments of the present disclosure. The semiconductor device 2′ has a similar structure to that of the semiconductor device 2. As shown in FIG. 2B, the multi-layered structure 20 includes a plurality of layers 21, 22 and 23. The layer 21 is disposed on the top surface 11a of the substrate 11. The layer 22 is stacked on the layer 21 and the layer 23 is stacked on the layer 22. The layers 21 and 23 are optically transparent layers which allow a light within a specific wavelength range to pass through while the layer 22 is a light blocking layer which does not allow the light within the above wavelength range to pass through. The light blocking layer 22 defines a plurality of apertures 22P. The apertures 22P are filled by the optically transparent layer 23 so that it allows the light within the above wavelength range to pass through.

FIG. 2C is a schematic top view of a semiconductor device in accordance with some embodiments of the present disclosure. As shown in FIG. 2C, the substrate 11 is a semiconductor wafer including a plurality of units, e.g., U1, U2, U3 and U4. Each unit includes at least one semiconductor chip. The multi-layered structure 20 (the top surface 20a and bottom surface 20b of the multi-layered structure are denoted) is disposed in each unit, covers the sensing region of the semiconductor chip and exposes the pad(s) 12 in each unit. In some embodiments as shown in FIG. 2C, a length L1 of a top surface 20a of the multi-layered structure 20 is smaller than a length L2 of a bottom surface 20b of the multi-layered structure 20. The multi-layered structure 20 extends outwardly beyond at an edge of a topmost surface 20a of the multi-layered structure 20. In some embodiments, the multi-layered structure 20 may extends outwardly beyond one edge of a topmost surface 20a of the multi-layered structure 20 (see U1 in FIG. 2C). In some embodiments, the multi-layered structure 20 may extends outwardly beyond a pair of opposing edges of a topmost surface 20a of the multi-layered structure 20 (see U2 in FIG. 2C). In some embodiments, the multi-layered structure 20 may extends outwardly beyond four edges of a topmost surface 20a of the multi-layered structure 20 (see U3 and U4 in FIG. 2C).

Referring back to FIG. 2A, the multi-layered structure 20 has a sidewall 20s. As shown in FIG. 2A, the sidewall 20s of the multi-layered structure 20 includes the sidewall 21s of the layer 21, the sidewall 22s of the layer 22 and the sidewall 23s of the layer 23. In some embodiments, the sidewalls of two adjacent layers may be connected by an exposed portion of a top surface of the lower layer. The exposed top surface of the lower layer (e.g., the layer 22) connecting the sidewalls (22s and 23s) may also be viewed as a part of the sidewall 20s of the multi-layered structure 20. The sidewall 20s is substantially smooth. In some embodiments, the sidewall 20s has a roughness (Ra) substantially the same as, or no greater than, a roughness of the top surface 20a of the multi-layered structure 20. In some embodiments, the sidewall has a roughness (Ra) of 100 nm or less, 90 nm or less, 80 nm or less, 70 nm or less, 60 nm or less, 50 nm or less, 40 nm or less, 30 nm or less, 20 nm or less, or 10 nm or less.

The sidewall 20s of the multi-layered structure 20 may taper from the bottom surface 20b of the multi-layered structure 20 to the top surface 20 of the multi-layered structure 20. In some embodiments, the sidewall 20s is stepped and tapers from the bottom surface 20b of the multi-layered structure 20 to the top surface 20 of the multi-layered structure 20 as shown in FIG. 2A and FIG. 2B.

The semiconductor device 2 may further comprise a light concentrating layer 15 disposed on the top surface 20a of the multi-layered structure 20. In some embodiments, the light concentrating layer 15 includes an array of microlens.

In some embodiments, the semiconductor package 2 includes a substrate 11 and a collimating structure 20. The substrate 11 includes a sensing region R1 and a pad 12. The collimating structure 20 is disposed on the substrate 11 and exposes the pad 12 of the substrate 11. In some embodiments, a length of a top surface of the collimating structure is smaller than a length of a bottom surface of the collimating structure. In some embodiments, a lower portion of the collimating structure extends outwardly beyond a lateral edge of a topmost surface of the collimating structure. In some embodiments, the collimating structure may be a multi-layered structure having the features as described above.

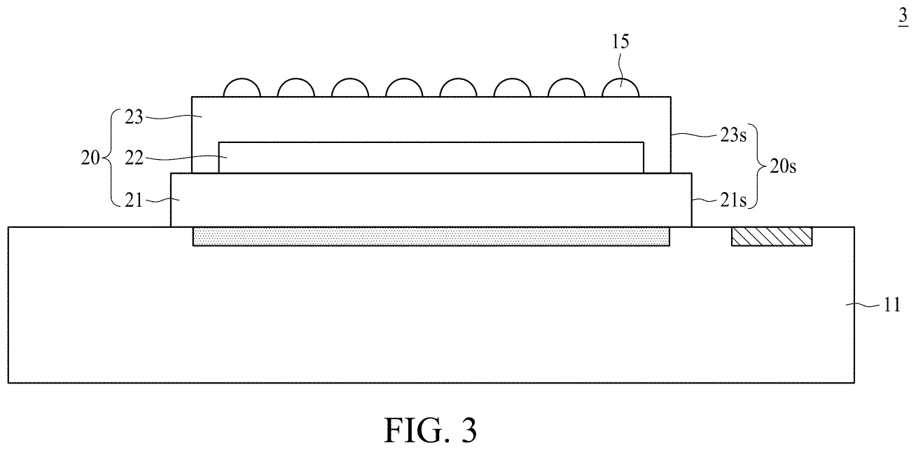

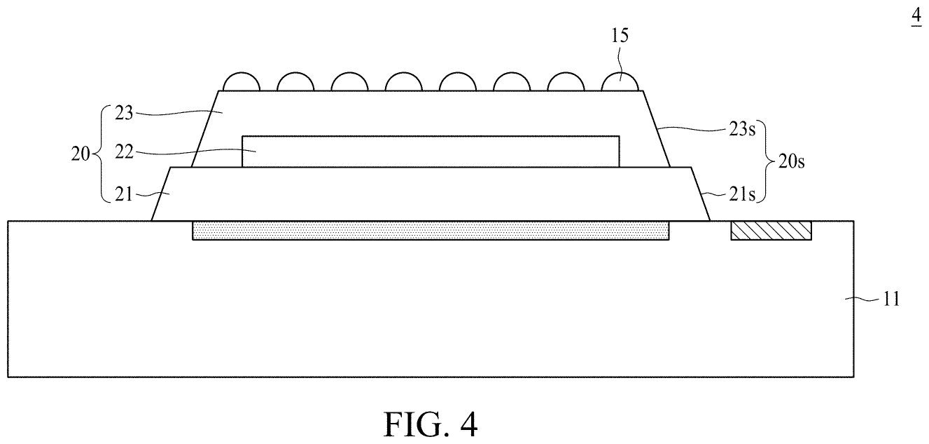

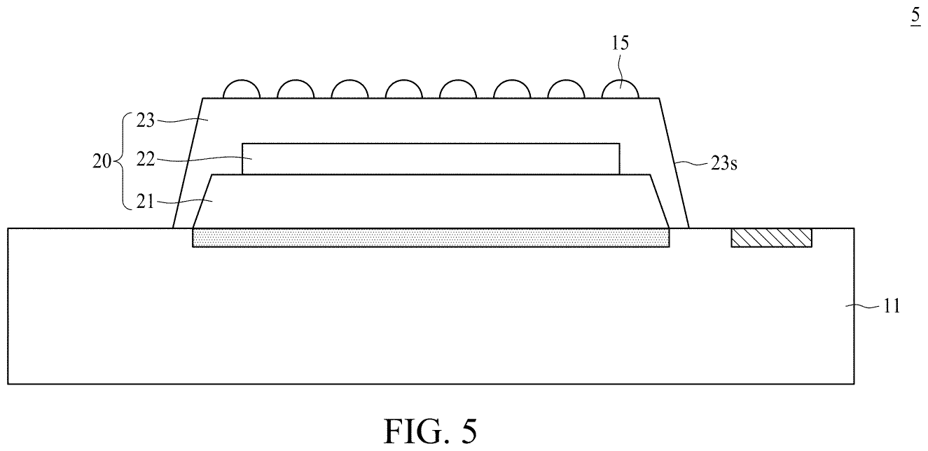

FIG. 3, FIG. 4 and FIG. 5 are a schematic cross-sectional view of a semiconductor device in accordance with some embodiments of the present disclosure. The semiconductor device 3, 4 and 5 shown in FIG. 3, FIG. 4 and FIG. 5 have a similar structure to that of the semiconductor device 2 except the configuration of the multi-layered structure 20. In some embodiments, one or more layers of the multi-layered structure 20 may be covered or fully covered by one or more layers stacked thereon. In some embodiments, the sidewall 20s of the multi-layered structure 20 or the sidewall of each layer of the multi-layered structure (e.g., 21s, 22s or 23s) may be titled. An angle between a sidewall and a corresponding top surface (for example, the sidewall 20s and the top surface 20a of the multi-layered structure 20) may be 90° or more. In some embodiments, an angle between a sidewall and a corresponding top surface may be greater than 90°.

As shown in FIG. 3, the multi-layered structure 20 include a plurality of layers 21, 22 and 23. The layer 22 is stacked on the layer 21. The layer 23 is stacked on the layer 22 and fully covers the layer 22 so that the layer 22 can be protected by the layer 23. The sidewall 20s of the multi-layered structure 20 includes the sidewall 21s of the layer 21 and the sidewall 23s of the layer 23.

As shown in FIG. 4, the multi-layered structure 20 include a plurality of layers 21, 22 and 23. The layer 22 is stacked on the layer 21. The layer 23 is stacked on the layer 22 and fully covers the layer 22 so that the layer 22 can be protected by the layer 23. The sidewall 20s of the multi-layered structure 20 includes the sidewall 21s of the layer 21 and the sidewall 23s of the layer 23. The sidewalls 21s and 23s are titled. The angle between the sidewall 21s and the top surface of layer 21 is greater than 90°. The angle between the sidewall 23s and the top surface of layer 23 is greater than 90°

As shown in FIG. 5, the multi-layered structure 20 include a plurality of layers 21, 22 and 23. The layer 22 is stacked on the layer 21. The layer 23 is stacked on the layer 22 and fully covers the layers 21 and 22 so that the layers 21 and 22 can be protected by the layer 23. The sidewall 20s of the multi-layered structure 20 includes the sidewall 23s of the layer 23. The sidewall 23s is titled. The angle between the sidewall 23s and the top surface of layer 23 is greater than 90°

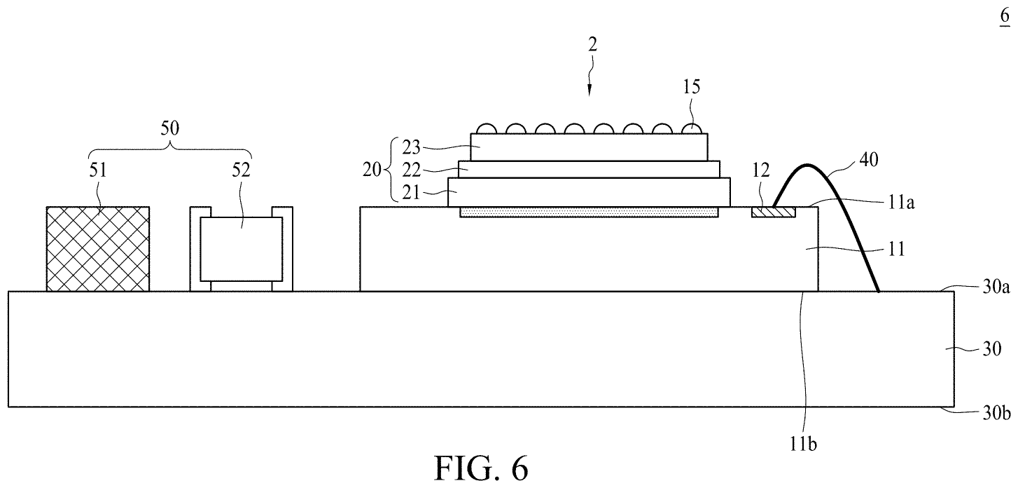

FIG. 6 is a schematic cross-sectional view of a semiconductor device package 6 in accordance with some embodiments of the present disclosure. As shown in FIG. 6, the semiconductor device package 6 includes a semiconductor device in accordance with the present disclosure (for example, the semiconductor device 2 as illustrated in FIG. 2) and a second substrate 30.

The second substrate 30 having a top surface 30a and a bottom surface 30b. The semiconductor device is disposed on, and electrically connected to, the top surface 30a of the second substrate 30. The semiconductor package 6 includes an electrical connection member 40 connecting the first substrate 11 of the semiconductor device 2 and the second substrate 30. In some embodiments, the electrical connection member 40 may be a wire and bonded to the pad 12 at the top surface 11a of the first substrate 11a of the semiconductor device 2 and a pad (not shown) at the top surface 30a of the second substrate 30. The second substrate 30 may be a printed circuit board (PCB), for example, a rigid PCB, a flexible PCB or a rigid-flex PCB. In some embodiments, a protective coating may be applied to cover the electrical connection member 40. The protective coating may be made of an epoxy resin.

The semiconductor device package 6 may further comprise one or more electronic components 50 (e.g., 51 and 52) disposed on the top surface 30a or bottom surface 30b of the second substrate 30. The electronic components 50 may include active components or a passive component. In some embodiments, the electronic components may include a resistor, an inductor or a capacitor.

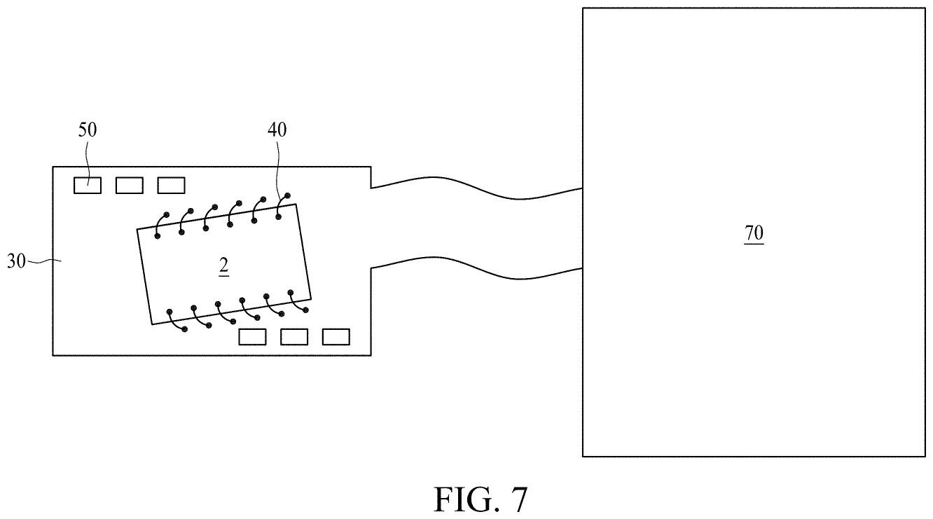

FIG. 7 is a schematic cross-sectional view of a semiconductor device package in accordance with some embodiments of the present disclosure. As shown in FIG. 7, the semiconductor device 2 is disposed on the second substrate 30 and electrically connected to the second substrate 30 by a wire 40. The semiconductor device package further comprises one or more electronic components 50 disposed on the second substrate 30. The second substrate 30 is a rigid-flex PCB and electrically connected to a mother board 70.

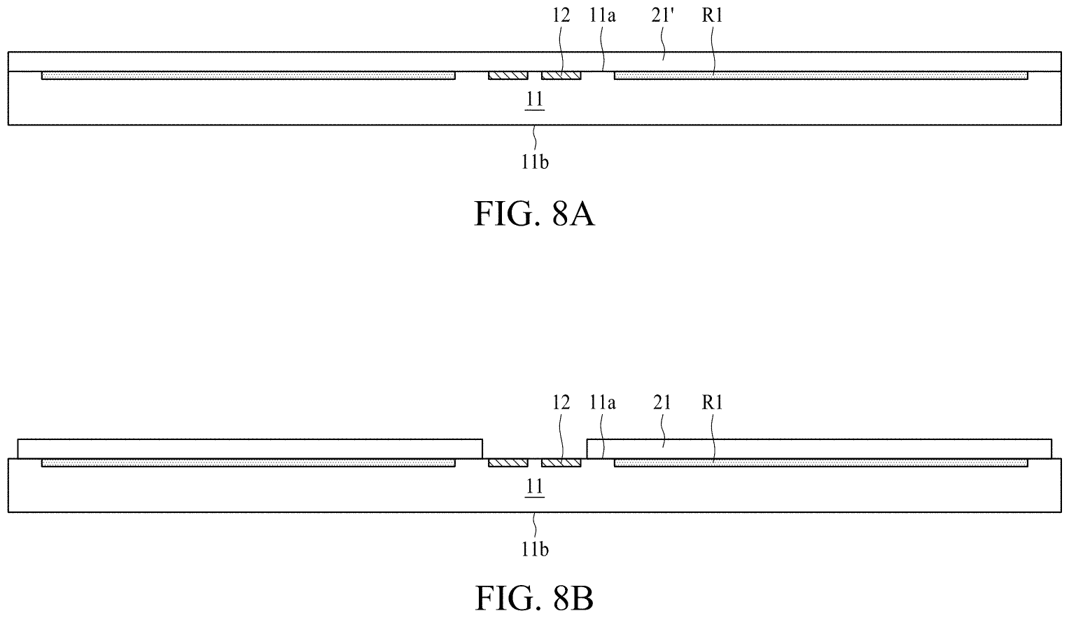

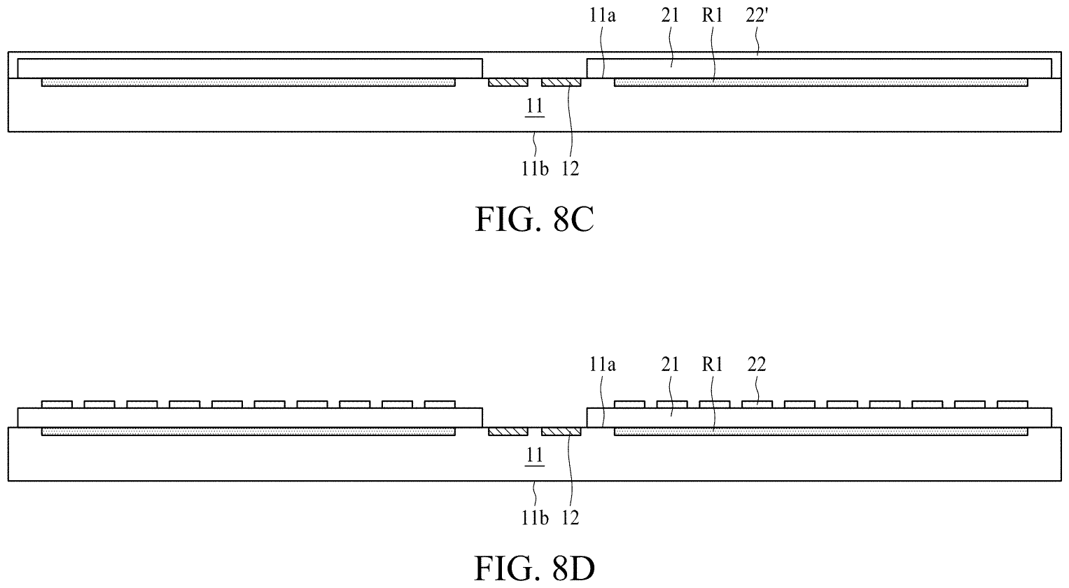

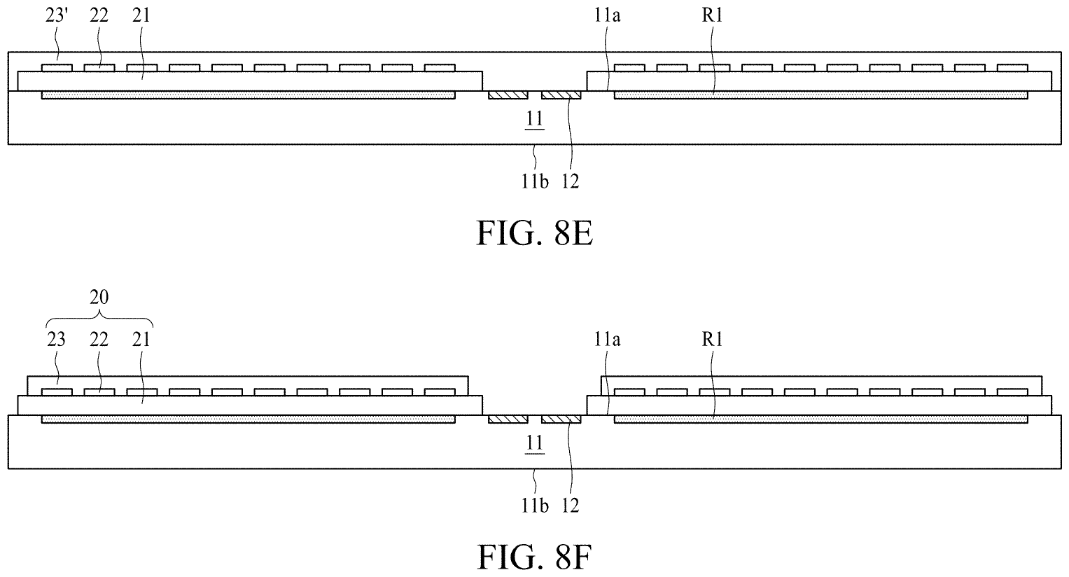

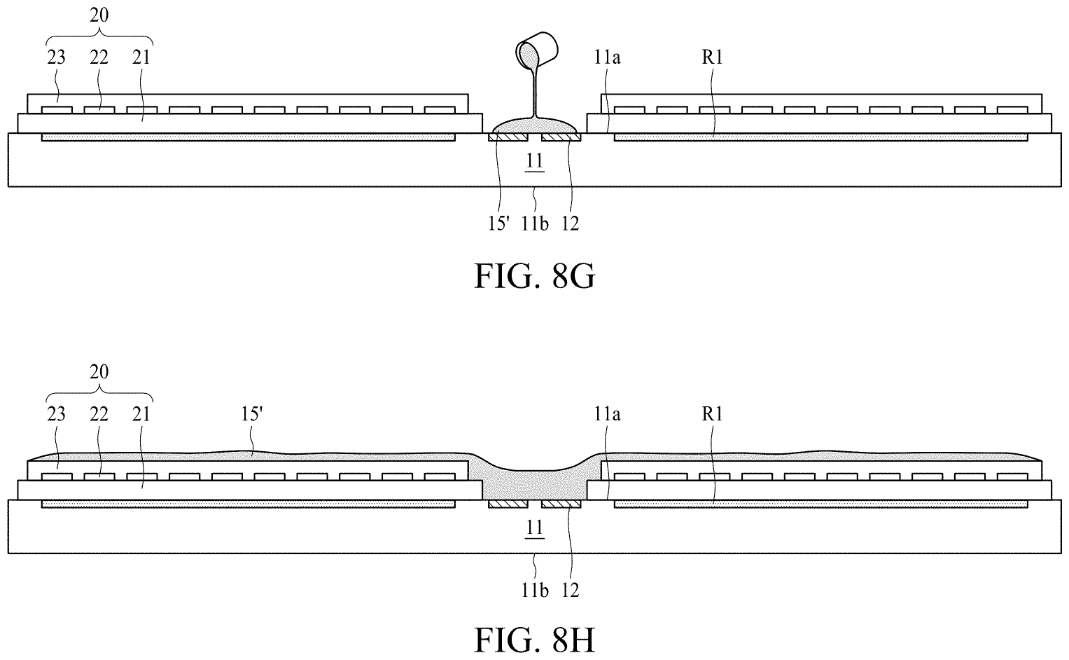

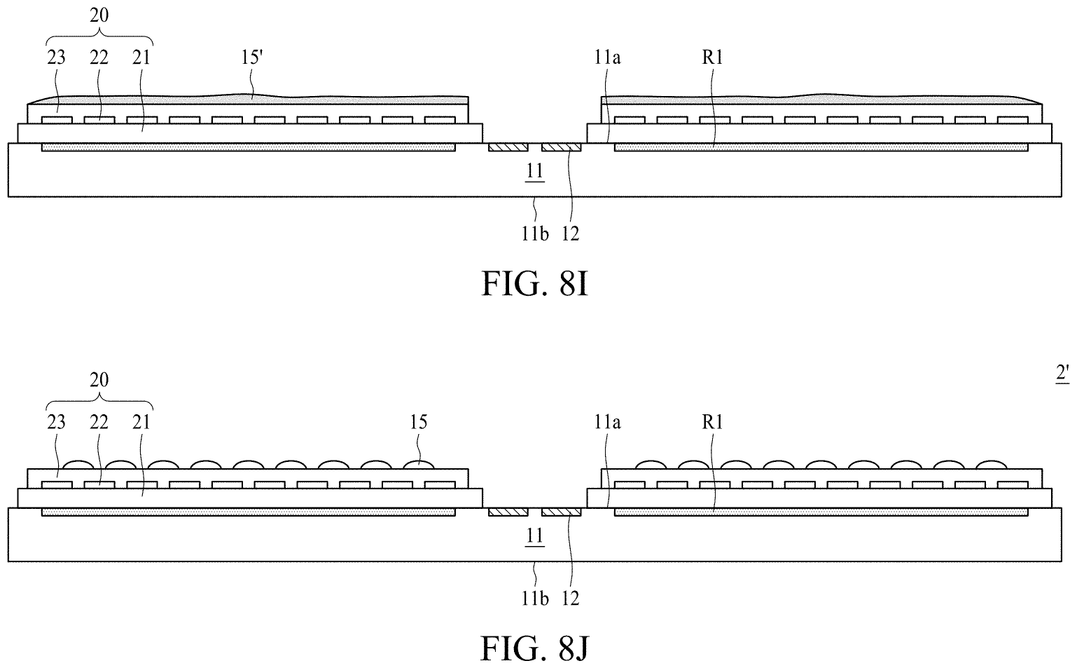

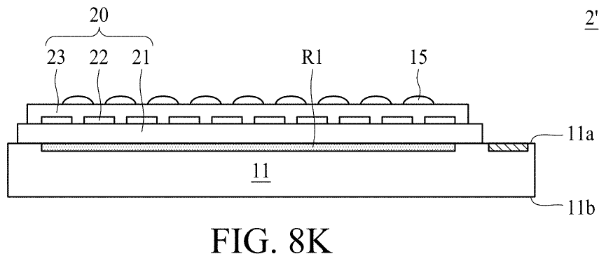

FIG. 8A, FIG. 8B, FIG. 8C, FIG. 8D, FIG. 8E, FIG. 8F, FIG. 8G, FIG. 8H, FIG. 8I, FIG. 8J and FIG. 8K illustrate operations of manufacturing a semiconductor electronic device in accordance with some embodiments of the present disclosure. As discussed below, each layer of the multi-layered structure may be formed by coating and photolithography operation including exposure and development processes. Optically-sensitive materials, such as photoresists, can be used to form the multi-layered structure. In some embodiments, a transparent photoresist may be used. In some embodiments, an opaque photoresist may be used.

Referring to FIG. 8A, a semiconductor wafer 11 is provided. The semiconductor wafer 11 has a top surface 11a and a bottom surface 11b. The top surface 11a of the wafer 11 includes a plurality of optical sensing regions R1 and pads 12. An optically-sensitive material 21′ is applied onto the top surface 11a of the wafer 11 by spin-coating or other suitable techniques, e.g., spray coating. The optically-sensitive material 21′ may be a photoresist.

Referring to FIG. 8B, the optically-sensitive material 21′ is patterned and forms a layer 21 by carrying out an exposure process and a development process. The layer 21 is an optically transparent layer. After the exposure process and the development process, a portion of the optically-sensitive material 21′ is removed and the pads 12 are exposed.

Referring to FIG. 8C, an optically-sensitive material 22′ is applied onto the structure formed in FIG. 8B by spin-coating or other suitable techniques, e.g., spray coating.

Referring to FIG. 8D, the optically-sensitive material 22′ is patterned and forms a layer 22 having a plurality of apertures by carrying out an exposure process and a development process. After the exposure process and the development process, a portion of the optically-sensitive material 22′ is removed, the pads 12 are exposed and the apertures are formed. The layer 22 is opaque and function as a light blocking layer so the light passes through the apertures, rather than the body of the layer 22.

Referring to FIG. 8E, an optically-sensitive material 23′ is applied onto the structure formed in FIG. 8D by spin-coating or other suitable techniques, e.g., spray coating. The optically-sensitive material 23′ fills the apertures defined by the layer 22.

Referring to FIG. 8F, the optically-sensitive material 23′ is patterned and forms a layer 23 by carrying out an exposure process and a development process. The layer 23 is an optically transparent layer. After the exposure process and the development process, a portion of the optically-sensitive material 22′ is removed, the pads 12 are exposed and the multi-layered structure including layers 21, 22 and 23 are formed.

Compared to the comparative embodiments, the multi-layered structure 20 in accordance with the embodiments of the present disclosure is manufactured layer-by-layer using coating and photolithography operation. Therefore, the configuration of the multi-layered structure 20 can be designed layer-by-layer, so that the sidewall of the multi-layered structure 20 can be easily modified to have a desired shape (for example, those illustrated in FIG. 2A, FIG. 2B and FIG. 2C and FIG. 3, FIG. 4 and FIG. 5) to facilitate the formation of a light concentrating layer (e.g., the optically-sensitive material for manufacturing the light concentrating layer is able to creep along the sidewall onto the top surface of the multi-layered structure without being splashed back by the sidewall). In addition, the pads 12 of the substrate 11 can be exposed after the formation of the multi-layered structure 20 without carrying out a slicing and/or physical bombardment operation, and therefore, layer delamination caused by the stress resulting from the slicing and/or physical bombardment operation used in comparative embodiments can be avoided.

FIGS. 8G to 8J illustrate operations of forming a light concentrating layer on a top surface of the multi-layered structure 20.

Referring to FIG. 8G and FIG. 8H, an optically-sensitive material 15′ that is suitable to form a light concentrating layer is applied onto the structure formed in FIG. 8F by spin-coating. In some embodiments, the optically-sensitive material 15′ may be applied using other suitable techniques. Due to the design of the sidewall (e.g., “a layer of the multi-layered structure extending outwardly beyond an edge of a topmost surface of the multi-layered structure” or “a length of a top surface of the multi-layered structure being smaller than a length of a bottom surface of the multi-layered structure”), the optically-sensitive material 15′ creeps along the sidewall to the top surface of the multi-layered structure during the operation of applying the optically-sensitive material 15′ and is retained on the top surface of the multi-layered structure after such operation.

Referring to FIG. 8I, an exposure process and development process are carried out to remove the optically-sensitive material 15′ that is not disposed on the top surface of the multi-layered structure.

Referring to FIG. 8J, the optically-sensitive material on the top surface of the multi-layered structure is cured, for example, by light irradiation, and a light concentrating layer 15 including an array of the microlens is formed. The microlens may be formed due to self-surface tension and cohesion of the optically-sensitive material 15′ during curing.

In some embodiments, a singulation process may be carried out to produce the structure as illustrated in FIG. 8K.

As used herein, the singular terms “a,” “an,” and “the” may include a plurality of referents unless the context clearly dictates otherwise.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if the difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range were explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein are described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations on the present disclosure.

What is claimed is:

1. A semiconductor package, comprising:
a semiconductor device comprising:
a first substrate, and
a multi-layered structure disposed on a top surface of the first substrate wherein a layer of the multi-layered structure extends outwardly beyond a lateral edge of a topmost surface of the multi-layered structure; and
a second substrate;
wherein the semiconductor device is disposed on and electrically connected to the second substrate.

2. The semiconductor package of claim 1, wherein the semiconductor device further comprises a light concentrating layer disposed on a top surface of the multi-layered structure.

3. The semiconductor device of claim 1, wherein the first substrate comprises a sensing region and a pad.

4. The semiconductor package of claim 1, wherein the first substrate is a silicon wafer or silicon chip.

5. The semiconductor package of claim 1, wherein the multi-layered structure comprises an optically transparent layer and a light blocking layer and wherein the light blocking layer defines a plurality of apertures.

6. The semiconductor package of claim 1, wherein the multi-layered structure has a sidewall and the sidewall of the multi-layered structure is substantially smooth.

7. The semiconductor package of claim 1, wherein the multi-layered structure has a sidewall and the sidewall of the multi-layered structure has a roughness (Ra) substantially the same as, or no greater than, a roughness of the top surface of the multi-layered structure.

8. The semiconductor package of claim 1, wherein the multi-layered structure has a sidewall and the sidewall of the multi-layered structure tapers from the bottom surface of the multi-layered structure to the top surface of the multi-layered structure.

9. The semiconductor package of claim 8, wherein the sidewall is stepped.

10. The semiconductor package of claim 1, wherein the multi-layered structure has a sidewall and an angle between the sidewall and the top surface of the multi-layered structure is 90° or more.

11. The semiconductor package of claim 1, further comprising an electrical connection member connecting to the first substrate and the second substrate.

12. A semiconductor package, comprising:
a semiconductor device comprising:
a first substrate having a sensing region and a pad, and
a collimating structure disposed on the first substrate and exposing the pad of the first substrate, wherein a length of a top surface of the collimating structure is smaller than a length of a bottom surface of the collimating structure; and
a second substrate;
wherein the semiconductor device is disposed on and electrically connected to the second substrate.

13. The semiconductor package of claim 12, wherein the semiconductor device further comprises an array of microlens disposed on the top surface of the collimating structure.

14. The semiconductor package of claim 12, wherein the collimating structure comprises an opaque layer defining a plurality of apertures.

15. The semiconductor package of claim 12, wherein the collimating structure has a sidewall and the sidewall has a roughness (Ra) substantially the same as, or no greater than, a roughness of the top surface of the collimating structure.

16. The semiconductor package of claim 12, wherein the collimating structure has a sidewall and the sidewall tapers from the bottom surface of collimating structure to the top surface of the collimating structure.

17. The semiconductor package of claim 16, wherein the sidewall is stepped.

18. The semiconductor package of claim 12, wherein the collimating structure has a sidewall and an angle between the sidewall and the top surface of collimating structure is 90° or more.

19. A method of manufacturing a semiconductor package, comprising:
providing a semiconductor device comprising:
a first substrate, and
a multi-layered structure disposed on a top surface of the first substrate wherein a layer of the multi-layered structure extends outwardly beyond an edge of a topmost surface of the multi-layered structure;
providing a second substrate;
disposing the semiconductor device on a top surface of the second substrate; and
electrically connecting the semiconductor device to the second substrate by wire bonding.

20. The method of claim 19, wherein the providing a semiconductor device comprises:
providing a first substrate having an optical sensing region and a non-optical sensing region; and
carrying out a photolithography process to form the multi-layered structure on the optical sensing region of the first substrate.
